(19) United States
(12) Patent Application Publication
(10) Pub. No.: US 2021/0134905 A1
(43) Pub. Date: May 6, 2021

(54) DISPLAY SUBSTRATE AND METHOD OF MANUFACTURING THE SAME, AND DISPLAY PANEL

(71) Applicant: BOE TECHNOLOGY GROUP CO., LTD., Beijing (CN)

(72) Inventors: Jianye ZHANG, Beijing (CN); Xiaoxin SONG, Beijing (CN)

(21) Appl. No.: 16/834,470

(22) Filed: Mar. 30, 2020

(30) Foreign Application Priority Data
Oct. 30, 2019 (CN) 201911043984.0

(51) Int. Cl. H01L 27/32; H01L 51/00; H01L 51/56

(52) U.S. Cl. CPC H01L 27/3248; H01L 27/3246; H01L 27/3258; H01L 2227/323; H01L 51/0018; H01L 51/56; H01L 27/3272

(57) ABSTRACT

A display substrate includes a base, and a gate metal layer, a source-drain metal layer, and a planarization layer that are all disposed above the base. The planarization layer is disposed at a side of the gate metal layer away from the base, and the source-drain metal layer is disposed between the gate metal layer and the planarization layer. The gate metal layer includes gate electrodes, and the source-drain metal layer includes source electrodes and drain electrodes. One of the gate electrodes, a respective one of the source electrodes, and a respective one of the drain electrodes are used to form a thin film transistor. The display substrate further includes auxiliary patterns disposed on surfaces of the source electrodes and the drain electrodes facing away from the base, the auxiliary patterns are in contact with the planarization layer, and a material of the auxiliary patterns includes at least one oleophobic material.

### CROSS-REFERENCE TO RELATED APPLICATION

This application claims priority and benefits to Chinese Patent Application No. 201911043984.0 filed on Oct. 30, 2019, which is incorporated herein by reference in its entirety.

### TECHNICAL FIELD

The present disclosure relates to the field of display technologies, and in particular, to a display substrate and a method of manufacturing the same, and a display panel.

### BACKGROUND

Organic light-emitting diode (OLED) displays formed by the printing technology have a longer service life and a better device performance than OLED displays formed by the evaporation technology, and thus the printing technology is a development direction of mass production of large-size OLED displays.

### SUMMARY

In an aspect, some embodiments of the present disclosure provide a display substrate. The display substrate includes: a base; a gate metal layer disposed above the base, the gate metal layer including a plurality of gate electrodes; a source-drain metal layer disposed at a side of the gate metal layer away from the base, the source-drain metal layer including a plurality of source electrodes and a plurality of drain electrodes, and one of the plurality of gate electrodes, a respective one of the plurality of source electrodes, and a respective one of the plurality of drain electrodes being used to form a thin film transistor; a planarization layer disposed at a side of the source-drain metal layer away from the base; and a plurality of auxiliary patterns disposed on surfaces of the plurality of source electrodes and the plurality of drain electrodes facing away from the base. The plurality of auxiliary patterns are in contact with the planarization layer, and a material of the plurality of auxiliary patterns includes at least one oleophobic material.

In some embodiments, at least one auxiliary pattern of the plurality of auxiliary patterns has a single-layer structure, and the at least one oleophobic material of the at least one auxiliary pattern includes an organic photoresist material or an inorganic material.

In some embodiments, the at least one auxiliary pattern of the plurality of auxiliary patterns includes a first sub-layer, a second sub-layer and a third sub-layer, which are all sequentially stacked in a direction away from the base toward the gate metal layer. The at least one oleophobic material includes an inorganic material and an organic photoresist material, a material of the first sub-layer is the inorganic material, a material of the second sub-layer is an amphiphilic material, and a material of the third sub-layer is the organic photoresist material.

In some embodiments, the planarization layer includes a first planarization sub-layer and a second planarization sub-layer that are sequentially stacked in a direction away from the base toward the gate metal layer, and the second planarization sub-layer covers the first planarization sub-layer and the plurality of auxiliary patterns.

In some embodiments, a material of the first planarization sub-layer and a material of the second planarization sub-layer are both an organic material. The planarization layer further includes a first spacer layer disposed between the first planarization sub-layer and the second planarization sub-layer, and a material of the first spacer layer is an inorganic material.

In some embodiments, a thickness of the first spacer layer is in a range from 500 Å to 1000 Å.

In some embodiments, the display substrate has a display area, and the display area includes a plurality of sub-pixel regions. The display substrate further includes: a plurality of light-emitting devices disposed at a side of the planarization layer away from the base and disposed in the display area, each light-emitting device includes a first electrode and a second electrode, and the first electrode is disposed between the planarization layer and the second electrode; and a pixel defining layer in a grid shape, each light-emitting device corresponds a respective one of a plurality of grids of the pixel defining layer. One of at least two thin film transistors disposed in a sub-pixel region of the display substrate is a driving transistor. A first electrode of a light-emitting device corresponding to the driving transistor is electrically connected to a drain electrode of the driving transistor through at least one first via hole extending through the planarization layer and a corresponding auxiliary pattern.

In some embodiments, the display substrate further includes an insulating layer disposed between the planarization layer and the plurality of light-emitting device. A material of the insulating layer is an inorganic material, a plurality of second via holes are disposed in the insulating layer, and an orthographic projection of each first via hole on the base is overlapped with an orthographic projection of a respective one of the plurality of second via holes on the base.

In another aspect, some embodiments of the present disclosure provide a display panel. The display panel includes the display substrate as described above.

In yet another aspect, some embodiments of the present disclosure provide a method of manufacturing a display substrate. The method includes: forming the gate metal layer including the plurality of gate electrodes above the base; forming the source-drain metal layer including the plurality of source electrodes and the plurality of drain electrodes above the gate metal layer, one of the plurality of gate electrodes, a respective one of the plurality of source electrodes, and a respective one of the plurality of drain electrodes are used to form a thin film transistor; forming the plurality of auxiliary patterns on surfaces of the plurality of source electrodes and the plurality of drain electrodes facing away from the base, a material of the plurality of auxiliary patterns includes at least one oleophobic material; and forming the planarization layer on the source-drain metal layer on which the plurality of auxiliary patterns have been formed.

In some embodiments, the at least one oleophobic material of the plurality of auxiliary patterns includes an organic photoresist material. Forming the plurality of auxiliary patterns on surfaces of the plurality of source electrodes and the plurality of drain electrodes facing away from the base, includes: forming a photoresist layer on the source-drain metal layer; and exposuring and developing the photoresist layer to form the plurality of auxiliary patterns on surfaces of the plurality of source electrodes and the plurality of drain electrodes facing away from the base.

In some embodiments, the at least one oleophobic material includes an inorganic material and an organic photoresist material. Forming the plurality of auxiliary patterns on surfaces of the plurality of source electrodes and the plurality of drain electrodes facing away from the base, includes: forming an inorganic material layer on the source-drain metal layer; forming an amphiphilic material layer on the inorganic material layer; forming a photoresist layer on amphiphilic material layer; and forming the plurality of auxiliary patterns on surfaces of the plurality of source electrodes and the plurality of drain electrodes facing away from the base through exposure, development, and etching processes. Each auxiliary pattern includes a first sub-layer a material of which is the inorganic material, a second sub-layer a material of which is the amphiphilic material, and a third sub-layer a material of which is the organic photoresist material.

In some embodiments, the at least one oleophobic material of the plurality of auxiliary patterns includes an inorganic material. Forming the plurality of auxiliary patterns on surfaces of the plurality of source electrodes and the plurality of drain electrodes facing away from the base, includes: forming an inorganic material layer on the source-drain metal layer; forming an amphiphilic material layer on the inorganic material layer; forming a photoresist layer on the amphiphilic material; exposing and developing the photoresist layer to form a plurality of third sub-layers; performing an etching process on the amphiphilic material layer and the inorganic material layer to form a plurality of second sub-layers and a plurality of first sub-layers respectively; and removing the plurality of third sub-layers and the plurality of second sub-layers, each first sub-layer serving as an auxiliary pattern.

In some embodiments, forming the planarization layer, includes: forming a first planarization sub-film of an organic material on the base above which the plurality of auxiliary patterns have been formed; forming a second planarization sub-film of an organic material on the first planarization sub-film and the plurality of auxiliary patterns through a non-horizontal contact manner; and etching the second planarization sub-film to form the planarization layer including a plurality of first via holes each extending through the second planarization sub-film.

In some embodiments, forming the planarization layer, includes: forming a first planarization sub-film of an organic material on the base above which the plurality of auxiliary patterns have been formed; forming a first spacer film of an inorganic material on the first planarization sub-film and the plurality of auxiliary patterns; forming a second planarization sub-film of a organic material on the first spacer film; and sequentially etching the second planarization sub-film and the first spacer film to form the planarization layer including a plurality of first via holes each extending through the second planarization sub-film and the first spacer film.

In some embodiments, the method further includes: forming a plurality of light-emitting devices each in a respective one of a plurality of sub-pixel regions, each light-emitting device including a first electrode and a second electrode. One of at least two thin film transistors in a sub-pixel region is a driving transistor, and a first electrode of a light-emitting device corresponding to the driving transistor is electrically connected to a drain electrode of the driving transistor through at least one first via hole extending through the planarization layer and a corresponding auxiliary pattern.

In some embodiments, forming the at least one first via hole extending through the planarization layer and the corresponding auxiliary pattern, includes: forming a photoresist layer on a planarization film through a non-horizontal contact manner; exposuring and developing the photoresist layer; and etching the planarization film and the corresponding auxiliary pattern to form the at least one first via hole extending through the planarization layer and the corresponding auxiliary pattern.

In some embodiments, before forming the at least one first via hole extending through the planarization layer and the corresponding auxiliary pattern, the method further includes: forming a second spacer film on a planarization film, a material of the second spacer film being an inorganic insulating material; forming a photoresist layer on the second spacer film; exposuring and developing the photoresist layer; and etching the second spacer film to form a second spacer layer including a plurality of second via holes. Forming the at least one first via hole extending through the planarization layer and the corresponding auxiliary pattern, includes: etching the planarization film and the corresponding auxiliary pattern by taking the second spacer layer formed with the plurality of second via holes as a mask to form the at least one first via hole extending through the planarization layer and the corresponding auxiliary pattern.

In some embodiments, before forming the at least one first via hole extending through the planarization layer and the corresponding auxiliary pattern includes: forming a second spacer film on a planarization film, a material of the second spacer film being a metal material; forming a photoresist layer on the second spacer film; exposuring and developing the photoresist layer; and etching the second spacer film to form a second spacer layer including a plurality of second via holes. Forming the at least one first via hole extending through the planarization layer and the corresponding auxiliary pattern, includes: etching the planarization film and the corresponding auxiliary pattern by using the second spacer layer including the plurality of second via holes as a mask to form the at least one first via hole extending through the planarization layer and the auxiliary pattern; and removing the second spacer layer.

### BRIEF DESCRIPTION OF THE DRAWINGS

In order to describe technical solutions in embodiments of the present disclosure more clearly, the accompanying drawings to be used in the description of embodiments will be introduced briefly below. Obviously, the accompanying drawings to be described below are merely some embodiments of the present disclosure, and a person of ordinary skill in the art may obtain other drawings according to these drawings without paying any creative effort.

FIG. 1 is a schematic top view of a display substrate, according to some embodiments of the present disclosure;

FIG. 2 is a schematic cross-sectional view of the display substrate along direction A-A′ in FIG. 1, according to some embodiments of the present disclosure;

FIG. 3 is a schematic cross-sectional view of the display substrate along the direction A-A′ in FIG. 1, according to some embodiments of the present disclosure;

FIG. 4 is a schematic cross-sectional view of the display substrate along the direction A-A′ in FIG. 1, according to some embodiments of the present disclosure;

FIG. 5 is a schematic cross-sectional view of the display substrate along the direction A-A′ in FIG. 1, according to some embodiments of the present disclosure;

FIG. 6 is a schematic cross-sectional view of the display substrate along the direction A-A′ in FIG. 1, according to some embodiments of the present disclosure;

FIG. 7 is a schematic cross-sectional view of the display substrate along the direction A-A′ in FIG. 1, according to some embodiments of the present disclosure;

FIG. 8 is a schematic flow chart of a method of manufacturing a display substrate, according to some embodiments of the present disclosure;

FIG. 9 is a schematic diagram showing a structure formed after a gate metal layer and a source-drain metal layer are formed above a base, according to some embodiments of the present disclosure;

FIG. 10 is a schematic diagram showing a structure formed after auxiliary patterns is formed on the basis of the structure shown in FIG. 9, according to some embodiments of the present disclosure;

FIG. 11 is a schematic diagram showing a structure formed after a photoresist layer is formed on the source-drain metal layer in FIG. 9, according to some embodiments of the present disclosure;

FIG. 12 is a schematic diagram showing a structure formed after an inorganic material layer, an amphiphilic material layer, and a photoresist layer are sequentially formed on the source-drain metal layer in FIG. 9, according to some embodiments of the present disclosure;

FIG. 13 is a schematic diagram showing a structure formed after the photoresist layer in FIG. 12 are exposed and developed, according to some embodiments of the present disclosure;

FIG. 14 is a schematic diagram showing a structure formed after auxiliary patterns are formed on the basis of the structure in FIG. 13, according to some embodiments of the present disclosure;

FIG. 15 is a schematic diagram showing a structure formed after a first planarization sub-film is formed on the basis of the structure in FIG. 10, according to some embodiments of the present disclosure;

FIG. 16A is a schematic diagram showing a structure formed after a second planarization sub-film is formed on the basis of the structure in FIG. 15, according to some embodiments of the present disclosure;

FIG. 16B is a schematic diagram showing a structure formed after the second planarization sub-film is etched to form a plurality of first via hole on the basis of the structure in FIG. 16A, according to some embodiments of the present disclosure;

FIG. 17 is a schematic diagram showing a structure formed after a first spacer film is formed on the basis of the structure in FIG. 15, according to some embodiments of the present disclosure;

FIG. 18A is a schematic diagram showing a structure formed after a second planarization sub-film is formed on the basis of the structure in FIG. 17, according to some embodiments of the present disclosure;

FIG. 18B is a schematic diagram showing a structure formed after a second planarization sub-film and the first spacer film are etched to form a plurality of first via hole on the basis of the structure in FIG. 18A, according to some embodiments of the present disclosure;

FIG. 19 is a schematic diagram showing a structure formed after a photoresist layer is formed on the basis of the structure in FIG. 16A, according to some embodiments of the present disclosure;

FIG. 20 is a schematic diagram of a structure formed after a second spacer film and a photoresist layer are formed on the basis of the structure in FIG. 16A, according to some embodiments of the present disclosure;

FIG. 21 is a schematic diagram showing a structure formed after a second spacer layer including second via holes is formed on the basis of the structure in FIG. 20, according to some embodiments of the present disclosure;

FIG. 22 is a schematic diagram showing a structure formed after first via holes are formed on the basis of the structure in FIG. 21, according to some embodiments of the present disclosure;

FIG. 23 is a schematic diagram showing a structure formed after a second spacer layer is removed on the basis of the structure in FIG. 22, according to some embodiments of the present disclosure; and

FIG. 24 is a schematic diagram showing another structure formed after first via holes are formed on the basis of the structure in FIG. 21, according to some embodiments of the present disclosure.

### DETAILED DESCRIPTION

In order to make the objectives, technical solutions and advantages in embodiments of the present disclosure clearer, the technical solutions in the embodiments of the present disclosure will be described clearly and completely with reference to the accompanying drawings in the embodiments of the present disclosure. Obviously, the described embodiments are merely some but not all of embodiments of the present disclosure. All other embodiments made on the basis of the embodiments of the present disclosure by a person of ordinary skill in the art without paying any creative effort shall be included in the protection scope of the present disclosure.

It will be understood that in the description of the present disclosure, orientations or positional relationships indicated by terms “center”, “upper”, “lower”, “front”, “rear”, “left”, “right”, “vertical”, “horizontal”, “top”, “bottom”, “inner”, “outer”, etc. are based on orientations or positional relationships shown in the drawings, merely to facilitate and simplify the description of the present disclosure, but not to indicate or imply that the referred devices or elements must have a particular orientation, or must be constructed or operated in a particular orientation. Therefore, they should not be construed as limitations to the present disclosure. The words “a plurality of” herein means two or more unless otherwise specified.

Unless the context requires otherwise, the term “comprise” and other forms thereof such as the third-person singular form “comprises” and the present participle form “comprising” in the description and the claims are construed as open and inclusive, i.e., “inclusive, but not limited to”. In the description of the description, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to same embodiment(s) or example(s). In addition, the specific features, structures, materials or characteristics may be included in any or more embodiments or examples in any suitable manner.

Below, terms “first” and “second” are only used for describing purposes, and cannot be construed as indicating or implying relative importance or implicitly indicating the number of technical features indicated. Thus, features defined with “first” and “second” may explicitly or implicitly include one or a plurality of the features.

If the term “and/or” is used to connect several objects, such as “A and/or B”, it should be understood as only A, only B, or A and B. That is, “A and/or B” includes three kinds of relationships.

Some embodiments of the present disclosure provide a display panel. The display panel is, for example, an organic light-emitting diode (OLED) display panel.

As shown in FIG. 1, the display panel includes a display substrate 1, and the display substrate 1 has a display area (also known as an active area, AA) A and a peripheral area S, for example, a peripheral area S disposed around the display area A. The peripheral area S is used for wiring, or at least one driving circuit (e.g., a gate driving circuit) is disposed in the peripheral area S. The display area A includes a plurality of sub-pixel regions Q, and a plurality of sub-pixels P are disposed in the plurality of sub-pixel regions Q in a one-to-one correspondence manner.

For example, as shown in FIG. 1, the plurality of sub-pixels P are arranged in a matrix. In this case, a same row of sub-pixels P that are arranged in a horizontal direction X may be connected to a gate line GL, and a same column of sub-pixels P that are arranged in a vertical direction Y may be connected to a data line DL. An arrangement of the plurality of sub-pixels P in a matrix in FIG. 1 is merely an example. For another example, among the plurality of sub-pixels P, sub-pixels P in odd rows are arranged in a matrix, sub-pixels P in even rows are arranged in a matrix, and in every two adjacent rows, a sub-pixel P in an even row corresponds to a region between two adjacent sub-pixels P in an odd row that are adjacent to the sub-pixel P in the even row.

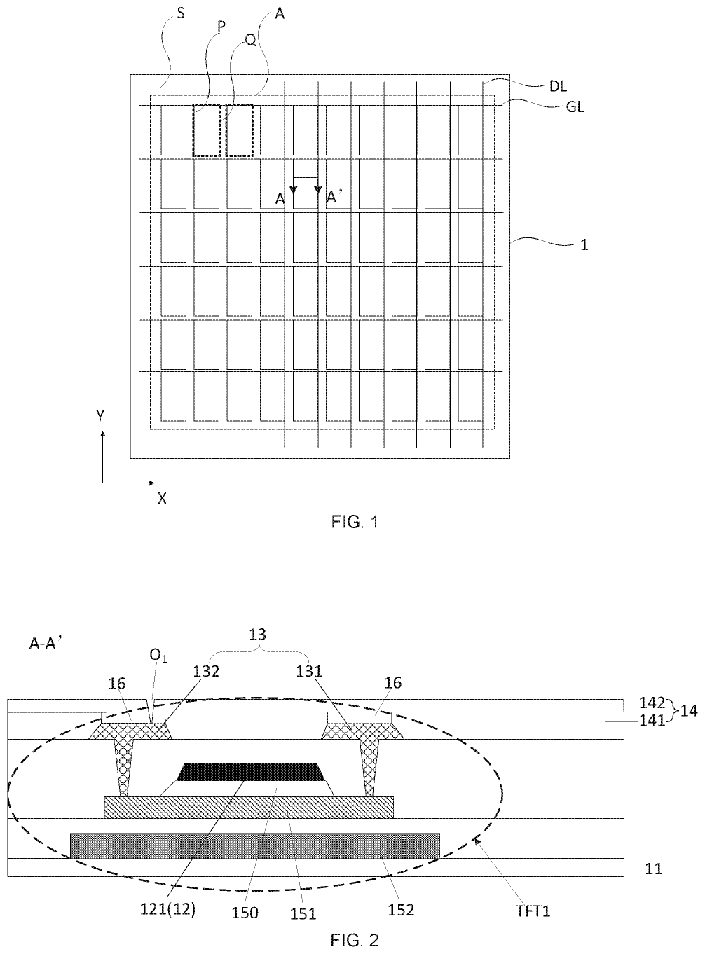

As shown in FIG. 2, the display substrate 1 includes a base 11, and a gate metal layer 12, a source-drain metal layer 13, and a planarization layer 14 that are all disposed above the base 11. The planarization layer 14 is disposed at a side of the gate metal layer 12 away from the base 11, and the source-drain metal layer 13 is disposed between the gate metal layer 12 and the planarization layer 14. As shown in FIG. 2, the gate metal layer 12 includes a plurality of gate electrodes 121, and the source-drain metal layer 13 includes a plurality of source electrodes 131 and a plurality of drain electrodes 132. One of the plurality of gate electrodes 121, a respective one of the plurality of source electrodes 131, and a respective one of the plurality of drain electrodes 132 are used to form a thin film transistor (TFT). In addition, as shown in FIGS. 1 and 2, the gate metal layer 12 may further include a plurality of gate lines GL, and the source-drain metal layer 13 may include a plurality of data lines DL. As shown in FIG. 1, the plurality of gate lines GL and the plurality of data lines DL are arranged crosswise and insulated from one another.

As shown in FIG. 2, in addition to the gate electrode 121, the source electrode 131, and the drain electrode 132, the thin film transistor further includes an active pattern 151 and a portion of a gate insulating layer 150 disposed between the gate electrode 121 and the active pattern 151. FIG. 2 illustrates the thin film transistor with a top-gate structure. In this case, the thin film transistor may further include a light-shielding pattern 152 disposed between the active pattern 151 and the base 11. The light-shielding pattern 152, the active pattern 151, the gate insulating layer 150, the gate electrode 121, and both the source electrode 131 and the drain electrode 132 are sequentially arranged in a direction away from the base 11 toward the planarization layer 14.

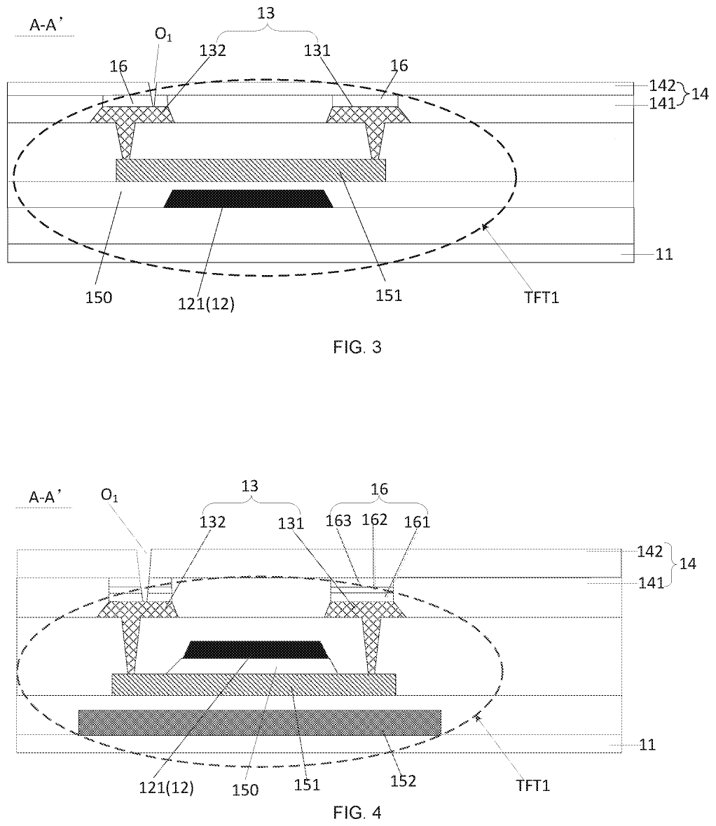

In some other embodiments, the thin film transistor has a bottom-gate structure. As shown in FIG. 3, the thin film transistor includes the gate electrode 121, a portion of the gate insulating layer 150, the active pattern 151, and both the source electrode 131 and the drain electrode 132 that are sequentially arranged in a direction away from the base 11 toward the planarization layer 14. Hereinafter, for convenience of description, the description will be made by taking an example in which the thin film transistor has the top-gate structure.

In some embodiments, in order to improve a degree of planarization, a material of the planarization layer 14 is an organic material.

In related art, the planarization layer is directly coated on the base where the plurality of source electrodes and the plurality of drain electrodes have been formed. After that, the material of the planarization layer may remain on the surfaces of the source and drain electrodes facing away from the base, and the material of lower portions in the planarization layer has a capillary phenomenon. That is, the material of the planarization layer has a topography following, which causes the maximum height difference between two positions on the surface of the planarization layer facing away from the base to be large.

In order to improve the defect, in some embodiments, as shown in FIG. 2, the display substrate 1 further includes a plurality of auxiliary patterns 16 disposed on surfaces of the plurality of source electrodes 131 and the plurality of drain electrodes 132 facing away from the base 11. The plurality of auxiliary patterns 16 are in contact with the planarization layer 14, and a material of the plurality of auxiliary patterns 16 includes at least one oleophobic material.

The oleophobic material is defined relative to the hydrophobic material. The surface of the oleophobic material is not compatible with the organic material. That is, the contact angle of the organic material on the oleophobic material is large, for example, greater than 90°, which makes the adhesion of the organic material to the oleophobic material is low, and a stable layer of the organic material cannot be formed on the oleophobic material.

In this way, when the planarization layer 14 is formed on the base 11 where the plurality of auxiliary patterns 16 have been formed, due to the presence of the oleophobic material of the auxiliary patterns 16, the organic material of the planarization layer 14 may be preferentially formed in lower positions, thereby improving the planarization effect.

In a manufacturing process of a display panel, especially in a manufacturing process of a large-sized display panel, in order to improve defects such as high voltage drop and the like caused by the excessive resistance of the gate lines GL and the data lines DL, thicknesses of the gate lines GL and the data lines DL may be increased. For example, a thickness of the gate lines GL and a thickness of the data lines DL are in a range of 1 μm to 2 μm, such as 1 μm, 1.2 μm, 1.4 μm, 1.6 μm, 1.8 μm or 2 μm.

It will be noted that, in a case where the thickness of the gate lines GL and the thickness of the data lines DL are increased, the thickness of the plurality of gate electrodes 121 belonging to the gate metal layer 12 together with the gate lines GL, and the thickness of the plurality of source electrodes 131 and the plurality of drain electrodes 132 belonging to the source-drain metal layer 13 together with the data lines DL are correspondingly increased. In this way, the thin film transistor is caused to be thicker. As a result, a substrate obtained after the source-drain metal layer 13 is formed has a greater height difference between different positions on the surface of the obtained substrate.

However, in the embodiments of the present disclosure, due to the arrangement of the plurality of auxiliary patterns 16 which may improve the planarization effect, the display substrate 1 may be applied to a large-sized display panel in which thicknesses of the gate metal layer 12 and the source-drain metal layer 13 are increased to reduce an IR drop.

In some embodiments, the at least one oleophobic material of at least one auxiliary pattern 16 includes at least one of an organic material or an inorganic material, and the at least one auxiliary pattern 16 has a single-layer structure or a multi-layer structure.

In order to facilitate patterning and reduce manufacturing processes, the at least one auxiliary pattern 16 has, for example, the following three possible structures.

In a first possible implementation, as shown in FIG. 2, the at least one auxiliary pattern 16 has a single-layer structure, and the oleophobic material of the at least one auxiliary pattern 16 includes an organic photoresist material.

The process of forming the auxiliary pattern 16 is as follows. A photoresist layer is formed first, and the photoresist material of the photoresist layer includes an organic material and a photoinitiator. Then the photoresist layer is exposured, during which the arrangement of molecular bonds on the surface of the organic material is changed in presence of the photoinitiator, and thus the surface of the organic material is changed from lipophilic to oleophobic. Finally, the photoresist layer is developed to remove the unexposed material.

In a second possible implementation, referring to FIG. 2, the at least one auxiliary pattern 16 has a single-layer structure, and the oleophobic material of the at least one auxiliary pattern 16 is an inorganic material.

In this case, for example, a process of forming a plurality of auxiliary patterns 16 includes: sequentially depositing an inorganic material layer, an amphiphilic material layer, and a photoresist layer in a thickness direction of the base 11; exposing and developing the photoresist layer to obtain a plurality of third sub-layer; sequentially etching the amphiphilic material layer and the inorganic material layer to obtain a plurality of second sub-layers of the amphiphilic material and a plurality of first sub-layers respectively; and removing the plurality of second sub-layers and the plurality of third sub-layers. The remaining first sub-layers are the auxiliary patterns 16. Herein, a purpose of forming the amphiphilic material layer is to improve adhesion between the inorganic material and the organic photoresist material.

The “sequentially etching” herein usually means one or more etching processes. For example, the amphiphilic material layer is etched by an etching liquid and then the inorganic material layer is etched by another etching liquid. Of course, if the materials of two layers are the same, the two layer may be etched by an etching liquid.

For example, the inorganic material of the inorganic material layer is silicon oxide (e.g., nano silicon oxide), or silicon nitride. The amphiphilic material of the amphiphilic material layer is, for example, hexamethyldisilazane (HMDS).

In a third possible implementation, as shown in FIG. 4, the at least one auxiliary pattern 16 includes a first sub-layer 161, a second sub-layer 162, and a third sub-layer 163, which are all sequentially stacked in a direction away from the base 11 toward the gate metal layer 12. The at least one oleophobic material of the at least one auxiliary pattern 16 includes an inorganic material and an organic photoresist material. A material of the first sub-layer 161 is the inorganic material, a material of the second sub-layer 162 is an amphiphilic material, and a material of the third sub-layer 162 is an organic photoresist material.

Relative to the second possible implementation, in the third possible implementation, the second sub-layers and the third sub-layers are not removed after the inorganic material layer is etched to form the plurality of first sub-layer 161.

For example, a process of forming a plurality of auxiliary patterns 16 includes: sequentially depositing the inorganic material layer, the amphiphilic material layer, and the photoresist layer in a thickness direction of the base 11; exposing and developing the photoresist layer to form the plurality of third sub-layers 163; and sequentially etching the amphiphilic material layer and the inorganic material layer to form the plurality of second sub-layers 162 and the plurality of first sub-layers 161 respectively, so that each auxiliary pattern 16 includes a first sub-layer 161, a second sub-layer 162, and a third sub-layer 163.

By forming the second sub-layer 162 between the first sub-layer 161 and the third sub-layer 163, the adhesion between the third sub-layer 163 and the first sub-layer 161 may be improved.

The planarization layer 14 may have a single-layer structure or a multi-layer structure, which is not limited herein.

In order to improve the degree of planarization of the planarization layer 14, in some embodiments, the planarization layer 14 has the multi-layer structure. For example, as shown in FIGS. 2 and 4, the planarization layer 14 includes a first planarization sub-layer 141 and a second planarization sub-layer 142 that are sequentially stacked in a direction away from the base 11 toward the gate metal layer 12, and the second planarization sub-layer 142 covers the first planarization sub-layer 141 and the plurality of auxiliary patterns 16. In this case, the planarization layer 14 is formed through two processes. Since the first planarization sub-layer 141 may not cover the plurality of auxiliary patterns 16 after the first planarization sub-layer 141 is formed, the second planarization sub-layer 142 may cover both the first planarization sub-layer 141 and the plurality of auxiliary patterns 16 in order to further improve the degree of planarization.

In order to meet a thickness requirement, in some embodiments, the first planarization sub-layer 141 and the second planarization sub-layer 142 are both made of an organic material, such as a silicone material.

In some embodiments, as shown in FIG. 5, the planarization layer 14 further includes a first spacer layer 143 disposed between the first planarization sub-layer 141 and the second planarization sub-layer 142, and a material of the first spacer layer 143 is an inorganic material. For example, the inorganic material is an insulating material, such as silicon oxide or silicon nitride.

Since there is a distance between the first planarization sub-layer 141 and the second planarization sub-layer 142 due to the first spacer layer 143, when the second planarization sub-layer 142 is coated, the uneven coating due to a tailing phenomenon that is caused by adhesion between the first planarization sub-layer 141 and the second planarization sub-layer 142 may be prevented, thereby further improving the planarization effect.

In an actual production process, in a case where the planarization layer 14 includes the first planarization sub-layer 141, the second planarization sub-layer 142 and the first spacer layer 143, the first planarization sub-layer 141, the second planarization sub-layer 142, and the first spacer layer 143 may be formed through a same patterning process, and the first spacer layer 143 does not need to be patterned separately.

On this basis, in some embodiments, a thickness of the first spacer layer 143 is in a range from 500 Å to 1000 Å. If the thickness of the first spacer layer 143 is very large, when the first planarization sub-layer 141, the second planarization sub-layer 142, and the first spacer layer 143 are patterned together, since there is a difference in etching rate between the first spacer layer 143 and both the first planarization sub-layer 141 and the second planarization sub-layer 142 (for example, an etching rate of the first planarization sub-layer 141 and the second planarization sub-layer 142 is fast, and an etching rate of the first spacer layer 143 is slow), there may be protrusion(s) after the first spacer layer 143 is etched. If the thickness of the first spacer layer 143 is too small, some positions on the first planarization sub-layer 141 may not be covered by the first spacer layer 143 due to nonuniformity of film deposition.

For example, the thickness of the first spacer layer 143 is 1000 Å. Of course, the thickness of the first spacer layer 143 is also, for example, 500 Å, 600 Å, 700 Å, 800 Å, or 900 Å.

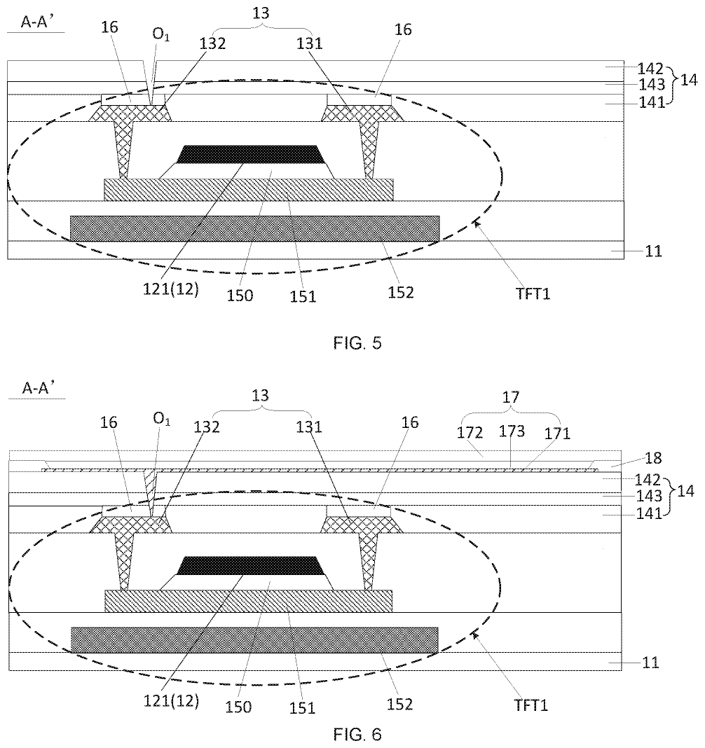

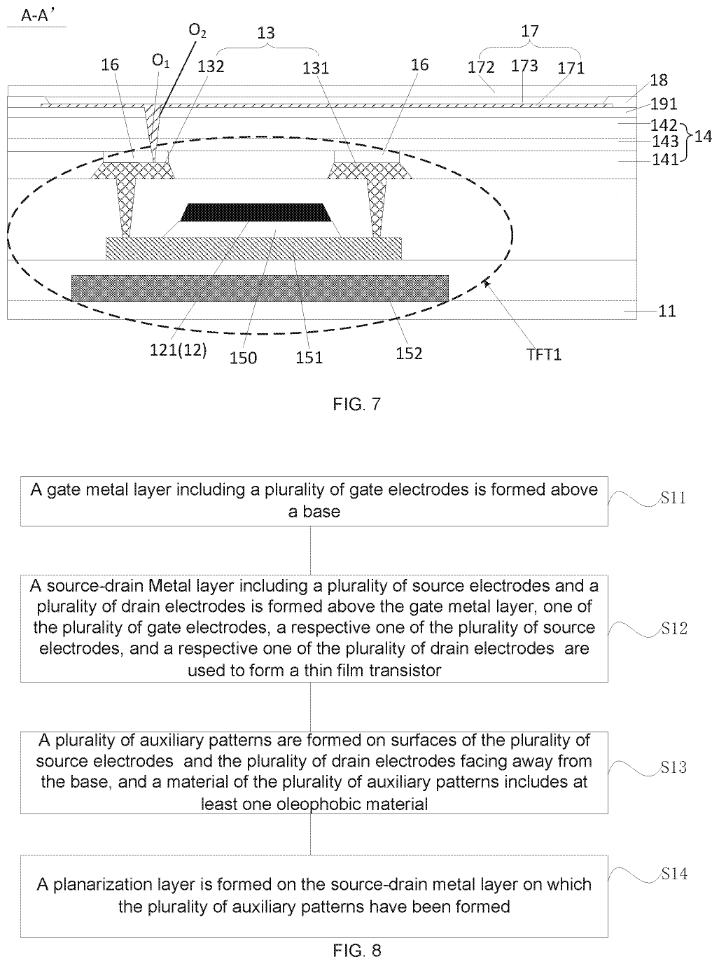

In some embodiments, as shown in FIGS. 6 and 7, the display substrate 1 further includes a plurality of light-emitting devices 17 disposed at a side of the planarization layer 14 away from the base 11 and disposed in the display area A, and a pixel defining layer 18 in a grid shape. For example, as shown in FIG. 6, the plurality of light-emitting devices 17 are disposed on a surface of the planarization layer 14 facing away from the base 1. Or there is at least one layer disposed between the planarization layer 14 and the plurality of light-emitting devices 17.

Each light-emitting device 17 corresponds to a respective one of a plurality of grids of the pixel defining layer 18, and each grid is an opening. That is, the plurality of grids of the pixel defining layer 18 are in one-to-one correspondence with the plurality of sub-pixel regions Q. The light-emitting device 17 includes a first electrode 171 and a second electrode 172, and the first electrode 171 is disposed between the planarization layer 14 and the second electrode 172.

The light-emitting device 17 may be driven by a circuit to emit light. The circuit includes at least two thin film transistors that are provided in a corresponding sub-pixel region Q, and one of the at least two thin film transistors is a driving transistor TFT1. For example, at least two thin film transistors are provided in each sub-pixel region Q. As shown in FIG. 6, the first electrode 171 of the light-emitting device 17 corresponding to the driving transistor TFT1 is electrically connected to a drain electrode 132 of the driving transistor TFT1 through at least one first via hole O₁, which extends through the planarization layer 14 and the auxiliary pattern 16. For example, the at least one first via hole O₁ includes one first via hole O₁.

Herein, the light-emitting device 17 may be an OLED light-emitting device. In this case, in addition to the first electrode 171 and the second electrode 172, the OLED light-emitting device further includes a light-emitting functional layer 173 disposed between the first electrode 171 and the second electrode 172. In some embodiments, the light-emitting functional layer 173 includes a light-emitting layer. In some other embodiments, in addition to the light-emitting layer, the light-emitting functional layer 173 further includes at least one of an electron transporting layer (ETL), an electron injection layer (EIL), a hole transporting layer (HTL), or a hole injection layer (HIL).

Before the pixel defining layer 18 and the plurality of light-emitting devices 17 are formed, due to the arrangement of the plurality of auxiliary patterns 16, a degree of planarization of the obtained substrate may be improved. Therefore, a requirement of the printing OLED technology on the degree of planarization may be met, thereby facilitating the manufacturing of the OLED light-emitting device by using the printing OLED technology, especially facilitating the manufacturing of a large-sized display panel. In addition, compared with the evaporation technology by which the OLED light-emitting device is formed, in the printing technology, a mask may be avoided, thereby saving costs.

In some embodiments, as shown in FIG. 7, the display substrate further includes an insulating layer 191 disposed between the planarization layer 14 and the plurality of light-emitting devices 17. A plurality of second via holes O₂ are provided in the insulating layer 191, and in the thickness direction of the base 11, an orthographic projection of each first via hole O₁ on the base 11 is overlapped with an orthographic projection of a respective one of the plurality of second via holes O₂ on the base 11. A material of the insulating layer 191 is an inorganic material, such as silicon oxide or silicon nitride.

For example, the process of forming the insulating layer 191 and the planarization layer 14 is as follows. A planarization film, an insulating film and a photoresist layer are formed sequentially, and then the photoresist layer is exposured and developed and the insulating film is etched to form the insulating layer 191 including the plurality of second via holes O₂. Then the planarization film is etched with the insulating layer 191 as a mask to form the planarization layer 14 including a plurality of first via holes O₁. Since the material of the insulating film is an inorganic material, the problem of adhesion when the photoresist layer is coated may be avoided.

Some embodiments of the present disclosure provide a method of manufacturing a display substrate, for example, the display substrate provided in any of the above embodiments. Referring to FIG. 8, the method includes S11 to S14.

In S11, referring to FIGS. 1 and 2, a gate metal layer 12 including a plurality of gate electrodes 121 is formed above a base 11.

In S12, referring to FIGS. 1 and 2, a source-drain metal layer 13 including a plurality of source electrodes 131 and a plurality of drain electrodes 132 is formed above the gate metal layer 12. One of the plurality of gate electrodes 121, a respective one of the plurality of source electrodes 131, and a respective one of the plurality of drain electrodes 132 are used to form a thin film transistor.

The gate metal layer 12 further includes a plurality of gate lines GL, and the source-drain metal layer 13 further includes a plurality of data lines DL. The plurality of gate lines GL and the plurality of data lines DL are disposed crosswise and insulated from one another. On this basis, each of the gate metal layer 12 and the source-drain metal layer 13 may be formed by a corresponding patterning process.

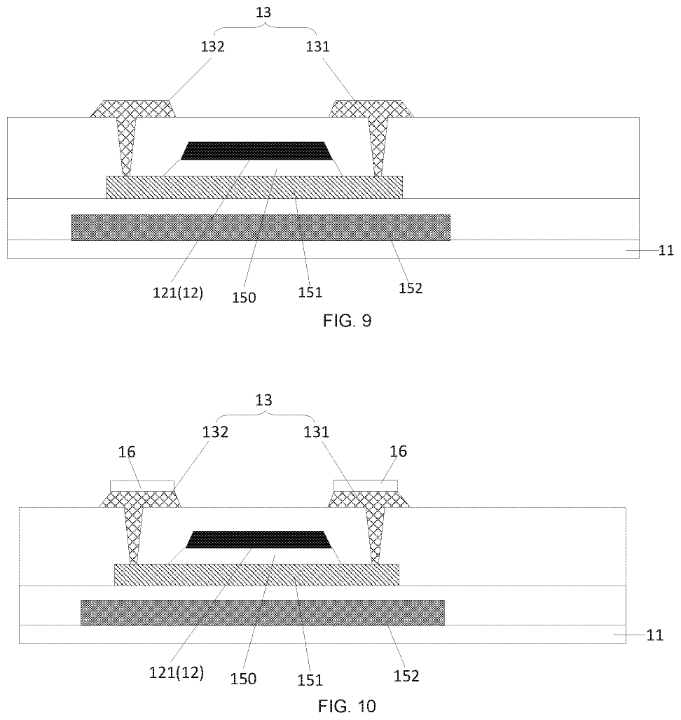

In addition to the gate electrode 121, the source electrode 131, and the drain electrode 132, the thin film transistor further includes an active pattern 151, a portion of a gate insulating layer 150 disposed between the gate electrode 121 and the active pattern 151, and a light-shielding pattern 152. On this basis, before the gate metal layer 12 and the source-drain metal layer 13 are formed above the base 11, the method may further include: sequentially forming the light-shielding pattern 152, the active pattern 151, and the gate insulating layer 150 on the base 11 to obtain a structure as shown in FIG. 9. A detailed manufacturing process is not described herein, a person skilled in the art may refer to related technologies.

In S13, referring to FIGS. 1 and 2, a plurality of auxiliary patterns 16 are formed on surfaces of the plurality of source electrodes 131 and the plurality of drain electrodes 132 facing away from the base 11, and a material of the plurality of auxiliary patterns 16 includes at least one oleophobic material.

In S14, referring to FIGS. 1 and 2, a planarization layer 14 is formed on the source-drain metal layer 13 on which the plurality of auxiliary patterns 16 have been formed.

The beneficial technical effects of the method of manufacturing the display substrate 1 provided by some embodiments of the present disclosure are the same as the beneficial technical effects of the display substrate 1 described above, and details are not described herein again.

According to different materials of the auxiliary pattern 16, the auxiliary pattern 16 may be obtained through different manufacturing processes.

In some embodiments, the oleophobic material of the plurality of auxiliary patterns 16 is an organic photoresist material. The step of forming the plurality of auxiliary patterns 16 on surfaces of the plurality of source electrodes 131 and the plurality of drain electrodes 132 facing away from the base 11, includes:

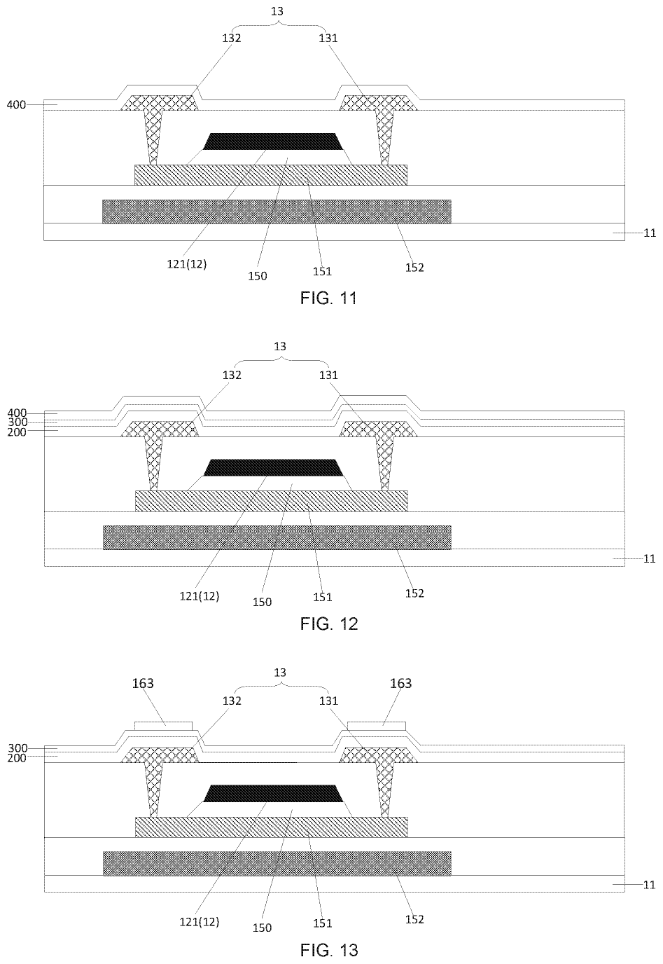

as shown in FIG. 11, forming a photoresist layer 400 on the source-drain metal layer 13; and

as shown in FIG. 10, exposuring and developing the photoresist layer 400 to form the plurality of auxiliary patterns 16 on surfaces of the plurality of source electrodes 131 and the plurality of drain electrodes 132 facing away from the base 11.

That is, the plurality of auxiliary patterns 16 are made of the organic photoresist material, and the process may be simplified compared with forming the plurality of auxiliary patterns 16 by using other materials.

In some other embodiments, the oleophobic material of the plurality of auxiliary patterns 16 is an inorganic material, such as silicon oxide (e.g., nano silicon oxide). As shown in FIG. 2, each auxiliary pattern 16 has a single-layer structure.

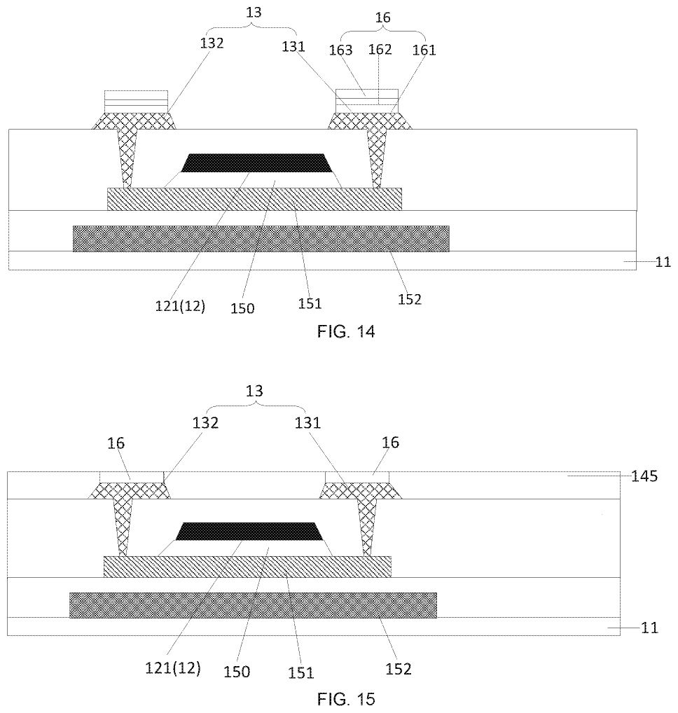

In this case, for example, the step of forming the plurality of auxiliary patterns 16 on surfaces of the plurality of source electrodes 131 and the plurality of drain electrodes 132 facing away from the base 11, includes: as shown in FIG. 12, sequentially forming an inorganic material layer 200, an amphiphilic material layer 300 and a photoresist layer 400 on the source-drain metal layer 13; as shown in FIG. 13, exposing and developing the photoresist layer 400 to obtain a plurality of third sub-layers 163; as shown in FIG. 14, sequentially etching the amphiphilic material layer 300 and the inorganic material layer 200 to obtain a plurality of second sub-layers 162 and a plurality of first sub-layers 161 respectively, the plurality of first sub-layers 161 being disposed on surfaces of the plurality of source electrodes 131 and the plurality of drain electrodes 132 facing away from the base 11; as shown in FIG. 10, removing the plurality of third sub-layers 163 and the plurality of second sub-layers 162. Each first sub-layer 161 serves as an auxiliary pattern 16. Herein, a purpose of forming the amphiphilic material layer 300 is to improve the adhesion between the inorganic material and the organic photoresist material.

For example, the inorganic material of the inorganic material layer 200 may be silicon oxide (e.g., nano silicon oxide), or silicon nitride. The amphiphilic material of the amphiphilic material layer 300 may be hexamethyldisilazane (HMDS).

In some other embodiments, the at least one oleophobic material of the plurality of auxiliary patterns 16 includes an inorganic material and an organic photoresist material. As shown in FIG. 4, the auxiliary pattern 16 has a multi-layer structure and the auxiliary pattern 16 includes a first sub-layer 161, a second sub-layer 162, and a third sub-layer 163, which are all sequentially stacked in a direction of the base 11 facing away from the base 11. A material of the first sub-layer 161 is the inorganic material, a material of the second sub-layer 162 is an amphiphilic material, and a material of the third sub-layer is the organic photoresist material.

For example, the step of forming the plurality of auxiliary patterns 16 on surfaces of the plurality of source electrodes 131 and the plurality of drain electrodes 132 facing away from the base 11, includes: sequentially depositing the inorganic material layer 200, the amphiphilic material layer 300 and the photoresist layer 400 on the source-drain metal layer 13; exposing and developing the photoresist layer 400 to obtain the plurality of third sub-layers 163; and sequentially etching the amphiphilic material layer 300 and the inorganic material layer 200 to obtain the plurality of second sub-layers 162 and the plurality of first sub-layers respectively, so that as shown in FIG. 14, the plurality of auxiliary patterns 16 are formed on surfaces of the plurality of source electrodes 131 and the plurality of drain electrodes 132 facing away from the base 11. In this way, the plurality of third sub-layers 163 and the plurality of second sub-layers 162 are not removed after the inorganic material layer 200 is etched.

Since the second sub-layer 162 is formed between the third sub-layer 163 and the first sub-layer 161, the adhesion between the third sub-layer 163 of the organic photoresist material and the first sub-layer 161 of the inorganic material may be improved.

In some embodiments, there are two possible implementations to form the planarization layer 14.

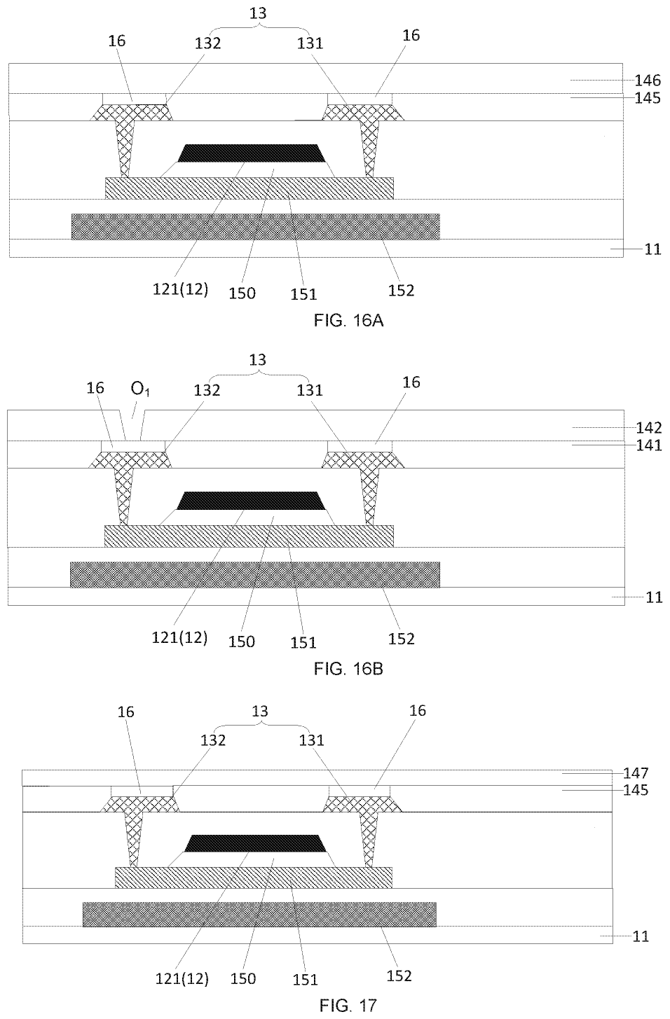

In a first possible implementation, as shown in FIG. 15, a first planarization sub-film 145 of an organic material is formed on the base 11 formed with the plurality of auxiliary patterns 16 to form the first planarization sub-layer 141. As shown in FIG. 16A, a second planarization sub-film 146 of an organic material is formed on the first planarization sub-layer 141 and the plurality of auxiliary patterns 16 through a non-horizontal contact manner. As shown in FIG. 16B, the second planarization sub-film 146 is etched to form the second planarization sub-layer 142 including a plurality of first via holes O₁ each extending through the second planarization sub-film 146 (i.e., a second planarization sub-layer 142 with via holes). In this way, the first planarization sub-layer 141 and the second planarization sub-layer 142 are formed, which constitute the planarization layer 14.

Since the material of the plurality of auxiliary patterns 16 includes the oleophobic material, and a material of the first planarization sub-film 145 is the organic material, when the first planarization sub-film 145 is formed on the base 11 formed with a plurality of auxiliary patterns 16, the organic material may be prevented from remaining on the surfaces of the auxiliary patterns 16 facing away from the base 11, so that the first planarization sub-film 145 may be preferentially formed at lower positions, and the degree of planarization may be improved.

On this basis, by forming the second planarization sub-film 146 on the first planarization sub-film 145 and the plurality of auxiliary patterns 16, the degree of planarization may be further improved.

The non-horizontal contact manner refers to a contact manner in which no force is generated in a horizontal direction of a plane where the first planarization sub-film 145 is located when the second planarization sub-film 146 is formed. For example, the second planarization sub-film 146 is formed by slit spraying or the like. Unlike the spin coating manner, the non-horizontal contact manner such as the slit spraying may avoid the following problem: when the second planarization sub-film 146 is formed on the first planarization sub-film 145 and the plurality of auxiliary patterns 16, due to presence of an organic solvent in a material for forming the second planarization sub-film 146, the material adheres to the first planarization sub-film 145 to cause a tailing phenomenon, thereby causing uneven coating.

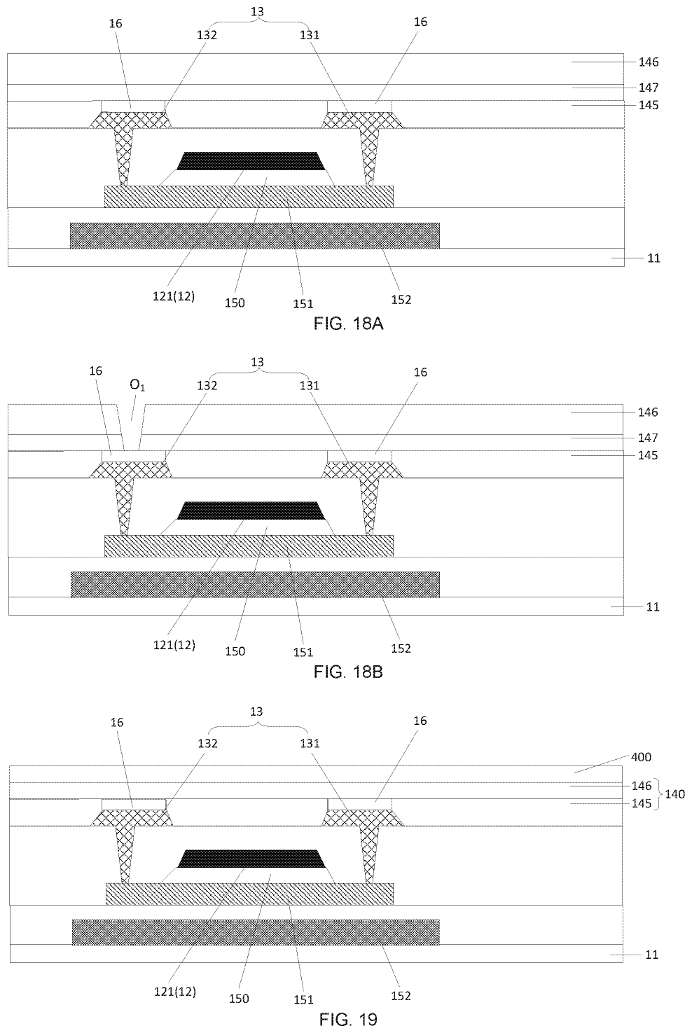

In a second possible implementation, as shown in FIG. 15, a first planarization sub-film 145 of an organic material is formed on the base 11 formed with the plurality of auxiliary patterns 16 to form a first planarization sub-layer 141. As shown in FIG. 17, a first spacer film 147 of an inorganic material is formed on the first planarization sub-film 145 and the plurality of auxiliary patterns 16. As shown in FIG. 18A, the second planarization sub-film 146 of the organic material is formed on the first spacer film 147. The inorganic material may be an insulating material, such as silicon oxide or silicon nitride.

As shown in FIG. 18B, The second planarization sub-film 146 and the first spacer film 147 are sequentially etched to form the second planarization sub-layer 142 and the first spacer layer 143 including a plurality of first via holes O₁ each extending through the second planarization sub-film 146 and the first spacer film 147. The second planarization sub-layer 142, the first spacer layer 143, and the first planarization sub-layer 141 constitute the planarization layer 14.

In this possible implementation, by spacing the first planarization sub-film 145 and the second planarization sub-film 146 with the first spacer film 147, the problem of uneven coating may be avoided, thereby improving the planarization effect.

In some embodiments, the display substrate 1 further includes a plurality of light-emitting devices 17 disposed at a side of the planarization layer 14 away from the base 11 and disposed in the display area A. Each light-emitting device 17 includes a first electrode 171 and a second electrode 172, and the first electrode 171 is disposed between the planarization layer 14 and the second electrode 172.

The light-emitting device 17 is driven by a circuit to emit light. Therefore, at least two thin film transistors are provided in a corresponding sub-pixel region Q, and one of the at least two thin film transistors is a driving transistor TFT1.

In this case, referring to FIG. 6, the method of manufacturing the display substrate 1 further includes: forming the plurality of light-emitting devices 17 each in a respective one of the plurality of sub-pixel regions Q. The light-emitting device 17 includes the first electrode 171 and the second electrode 172. The first electrode 171 of the light-emitting device corresponding to the driving transistor TFT1 is electrically connected to a drain electrode of the driving transistor TFT1 through at least one first via hole O₁ extending through the planarization layer 14 and a corresponding auxiliary pattern 16.

In a case where the planarization layer 14 includes the first planarization sub-layer 141, the second planarization sub-layer 142, and the first spacer layer 143, the first via hole O₁ may be formed in the planarization layer 14 through a same patterning process without separately patterning the first spacer layer 143.

For example, there may be two possible implementations to form the at least one first via hole O₁ extending through the planarization layer 14 and the corresponding auxiliary pattern 16 in the sub-pixel region Q.

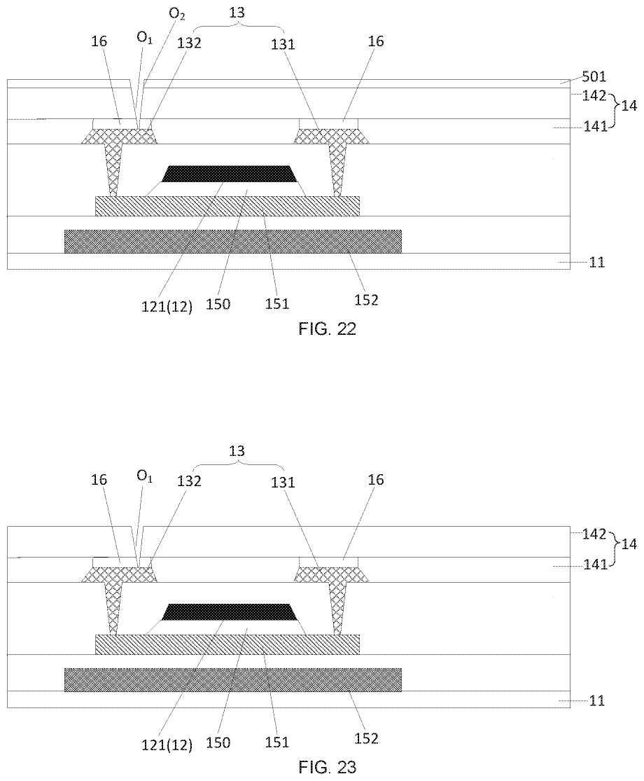

In a first possible implementation, as shown in FIG. 19, a photoresist layer 400 is formed on the planarization film 140 through the non-horizontal contact manner. For example, the planarization film 140 includes the first planarization sub-film 145 and the second planarization sub-film 146, and the photoresist layer 400 is formed on the second planarization sub-film 146. The photoresist layer 400 is exposured and developed and the second planarization film 146 and the corresponding auxiliary pattern 16 are etched to form the at least one first via hole O₁ extending through the planarization layer 14 and the corresponding auxiliary pattern 16 (as shown in FIG. 22).

The non-horizontal contact manner refers to a contact manner in which no force is generated in a horizontal direction of a plane where the planarization film 140 is located when the photoresist layer 400 is formed. For example, the photoresist layer 400 is formed by slit spraying or the like. Unlike the spin coating method, the non-horizontal contact method such as the slit spraying may avoid the following problem: when the photoresist layer 400 is formed on the planarization film 140, due to presence of an organic solvent in the photoresist material, the photoresist material adheres to the planarization film 140 to cause a tailing phenomenon, thereby causing uneven coating.

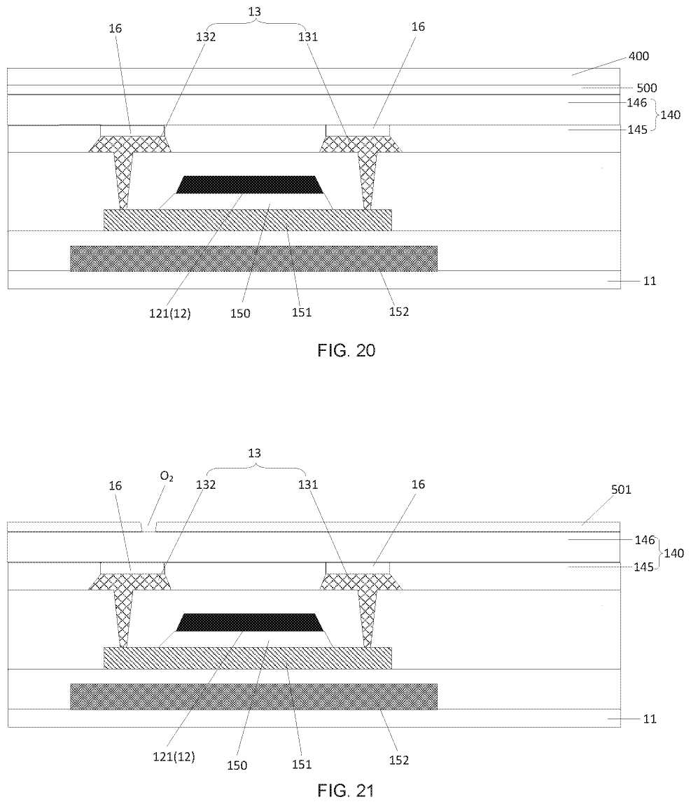

In a second possible implementation, before forming the at least one first via hole O₁ extending through the planarization layer 14 and an auxiliary pattern 16 in the sub-pixel region Q, as shown in FIG. 20, the method of manufacturing the display substrate 1 further includes:

sequentially forming a second spacer film 500 and a photoresist layer 400 on the planarization film 140. For example, the planarization film 140 includes the first planarization sub-film 145 and the second planarization sub-film 146, and the second spacer film 500 and the photoresist layer 400 are sequentially formed on the second planarization sub-film 146. As shown in FIG. 21, the photoresist layer 400 is exposured and developed and the second spacer film 500 is etched to form a second spacer layer 501 including a plurality of second via holes O₂.

In this possible implementation, by spacing the planarization film 140 and the photoresist layer 400 with the second spacer film 500, the problem of uneven coating may be avoided as well, thereby improving the planarization effect.

For example, a material of the second spacer film 500 is an inorganic insulating material or a metal material. The inorganic insulating material is, for example, silicon oxide or silicon nitride.

In the example where a material of the second spacer film 500 is an inorganic insulating material or a metal material, there may be two possible implementations to form the at least one first via hole O₁ extending through the planarization layer 14 and the corresponding auxiliary pattern 16 in the sub-pixel region Q.

In a first possible implementation, a material of the second spacer film 500 is a metal material. In this case, forming the at least one first via hole O₁ extending through the planarization layer 14 and the corresponding auxiliary pattern 16 in the sub-pixel region Q, includes: as shown in FIG. 22, etching the planarization film 140 and the corresponding auxiliary pattern 16 by using the second spacer layer 501 including the plurality of second via holes O₂ as a mask to form the at least one first via hole O₁ extending through the planarization layer 14 and the corresponding auxiliary pattern 16 in the sub-pixel region Q; and then, as shown in FIG. 23, removing the second spacer layer 501.

In a second possible implementation, a material of the second spacer film 500 is an inorganic insulating material. Compared with the first possible implementation, in the second possible implementation, the second spacer layer 501 may not be removed after the planarization layer 14 is formed.

That is, forming the at least one first via hole O₁ extending through the planarization layer 14 and the corresponding auxiliary pattern 16 in the sub-pixel region Q, includes: as shown in FIG. 22, etching the planarization film 140 and the corresponding auxiliary pattern 16 by using the second spacer layer 501 including the plurality of second via holes O₂ as a mask to form the at least one first via hole O₁ extending through the planarization layer 14 and the auxiliary pattern 16 in the sub-pixel region Q.

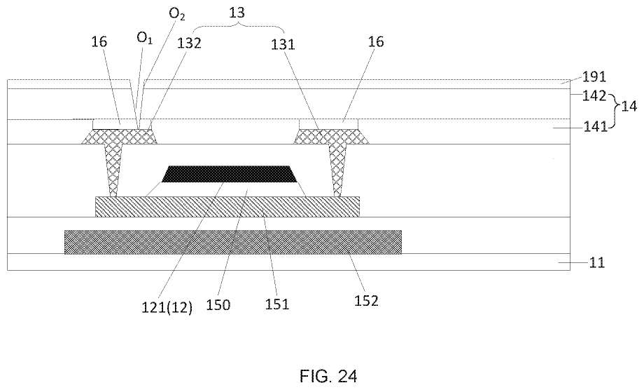

In this case, as shown in FIG. 24, the second spacer layer 501 is the insulating layer 191 in the display substrate 1.

The protection scope of the present disclosure is not limited thereto. Any person skilled in the art could readily conceive of changes or replacement within the technical scope of the present disclosure, which shall all be included in the protection scope of the present disclosure. Therefore, the protection scope of the present disclosure shall be determined by the protection scope of the claims.

What is claimed is:

1. A display substrate, comprising:
a base;
a gate metal layer disposed above the base, the gate metal layer including a plurality of gate electrodes;
a source-drain metal layer disposed at a side of the gate metal layer away from the base, wherein the source-drain metal layer includes a plurality of source electrodes and a plurality of drain electrodes, and one of the plurality of gate electrodes, a respective one of the plurality of source electrodes, and a respective one of the plurality of drain electrodes are used to form a thin film transistor;
a planarization layer disposed at a side of the source-drain metal layer away from the base; and
a plurality of auxiliary patterns disposed on surfaces of the plurality of source electrodes and the plurality of drain electrodes facing away from the base, wherein the plurality of auxiliary patterns are in contact with the planarization layer, and a material of the plurality of auxiliary patterns includes at least one oleophobic material.

2. The display substrate according to claim 1, wherein at least one auxiliary pattern of the plurality of auxiliary patterns has a single-layer structure, and the at least one oleophobic material of the at least one auxiliary pattern includes an organic photoresist material or an inorganic material.

3. The display substrate according to claim 1, wherein at least one auxiliary pattern of the plurality of auxiliary patterns includes a first sub-layer, a second sub-layer and a third sub-layer, which are all sequentially stacked in a direction away from the base toward the gate metal layer,
the at least one oleophobic material includes an inorganic material and an organic photoresist material,
a material of the first sub-layer is the inorganic material, a material of the second sub-layer is an amphiphilic material, and a material of the third sub-layer is the organic photoresist material.

4. The display substrate according to claim 1, wherein the planarization layer includes a first planarization sub-layer and a second planarization sub-layer that are sequentially stacked in a direction away from the base toward the gate metal layer, and the second planarization sub-layer covers the first planarization sub-layer and the plurality of auxiliary patterns.

5. The display substrate according to claim 4, wherein a material of the first planarization sub-layer and a material of the second planarization sub-layer are both an organic material; and
the planarization layer further includes a first spacer layer disposed between the first planarization sub-layer and the second planarization sub-layer, and a material of the first spacer layer is an inorganic material.

6. The display substrate according to claim 5, wherein a thickness of the first spacer layer is in a range from 500 Å to 1000 Å.

7. The display substrate according to claim 1, wherein the display substrate has a display area, and the display area includes a plurality of sub-pixel regions;
the display substrate further comprises:
a plurality of light-emitting devices disposed at a side of the planarization layer away from the base and disposed in the display area, wherein each light-emitting device includes a first electrode and a second electrode, and the first electrode is disposed between the planarization layer and the second electrode; and
a pixel defining layer in a grid shape, wherein each light-emitting device corresponds to a respective one of a plurality of grids of the pixel defining layer, wherein
one of at least two thin film transistors disposed in a sub-pixel region of the display substrate is a driving transistor, and a first electrode of a light-emitting device corresponding to the driving transistor is electrically connected to a drain electrode of the driving transistor through at least one first via hole extending through the planarization layer and a corresponding auxiliary pattern.

8. The display substrate according to claim 7, further comprising an insulating layer disposed between the planarization layer and the plurality of light-emitting devices, wherein
a material of the insulating layer is an inorganic material, a plurality of second via holes are disposed in the insulating layer, and an orthographic projection of each first via hole on the base is overlapped with an orthographic projection of a respective one of the plurality of second via holes on the base.

9. A display panel, comprising the display substrate according to claim 1.

10. A method of manufacturing the display substrate according to claim 1, the method comprising:
forming the gate metal layer including the plurality of gate electrodes above the base;
forming the source-drain metal layer including the plurality of source electrodes and the plurality of drain electrodes above the gate metal layer, wherein one of the plurality of gate electrodes, a respective one of the plurality of source electrodes, and a respective one of the plurality of drain electrodes are used to form a thin film transistor;
forming the plurality of auxiliary patterns on surfaces of the plurality of source electrodes and the plurality of drain electrodes facing away from the base, wherein a material of the plurality of auxiliary patterns includes at least one oleophobic material; and
forming the planarization layer on the source-drain metal layer on which the plurality of auxiliary patterns have been formed.

11. The method according to claim 10, wherein the at least one oleophobic material of the plurality of auxiliary patterns includes an organic photoresist material, and forming the plurality of auxiliary patterns on surfaces of the plurality of source electrodes and the plurality of drain electrodes facing away from the base, includes:
forming a photoresist layer on the source-drain metal layer; and
exposuring and developing the photoresist layer to form the plurality of auxiliary patterns on surfaces of the plurality of source electrodes and the plurality of drain electrodes facing away from the base.

12. The method according to claim 10, wherein the at least one oleophobic material includes an inorganic material and an organic photoresist material, and forming the plurality of auxiliary patterns on surfaces of the plurality of source electrodes and the plurality of drain electrodes facing away from the base, includes:
forming an inorganic material layer on the source-drain metal layer;
forming an amphiphilic material layer on the inorganic material layer;
forming a photoresist layer on the amphiphilic material layer; and
forming the plurality of auxiliary patterns on surfaces of the plurality of source electrodes and the plurality of drain electrodes facing away from the base through exposure, development, and etching processes, wherein each auxiliary pattern includes a first sub-layer a material of which is the inorganic material, a second sub-layer a material of which is an amphiphilic material, and a third sub-layer a material of which is the organic photoresist material.

13. The method according to claim 10, wherein the at least one oleophobic material of the plurality of auxiliary patterns includes an inorganic material, and forming the plurality of auxiliary patterns on surfaces of the plurality of source electrodes and the plurality of drain electrodes facing away from the base, includes:
forming an inorganic material layer on the source-drain metal layer;
forming an amphiphilic material layer on the inorganic material layer;
forming a photoresist layer on the amphiphilic material layer;
exposing and developing the photoresist layer to form a plurality of third sub-layers;
performing an etching process on the amphiphilic material layer and the inorganic material layer to form a plurality of second sub-layers and a plurality of first sub-layers respectively; and
removing the plurality of third sub-layers and the plurality of second sub-layers, each first sub-layer serving as an auxiliary pattern.

14. The method according to claim 10, wherein forming the planarization layer, includes:
forming a first planarization sub-film of an organic material on the base above which the plurality of auxiliary patterns have been formed;
forming a second planarization sub-film of an organic material on the first planarization sub-film and the plurality of auxiliary patterns through a non-horizontal contact manner; and
etching the second planarization sub-film to form the planarization layer including a plurality of first via holes each extending through the second planarization sub-film.

15. The method according to claim 10, wherein forming the planarization layer, includes:
forming a first planarization sub-film of an organic material on the base above which the plurality of auxiliary patterns have been formed;
forming a first spacer film of an inorganic material on the first planarization sub-film and the plurality of auxiliary patterns;
forming a second planarization sub-film of a organic material on the first spacer film; and
sequentially etching the second planarization sub-film and the first spacer film to form the planarization layer including a plurality of first via holes each extending through the second planarization sub-film and the first spacer film.

16. The method according to claim 10, further comprising:
forming a plurality of light-emitting devices each in a respective one of a plurality of sub-pixel regions, each light-emitting device including a first electrode and a second electrode, wherein one of at least two thin film transistors in a sub-pixel region is a driving transistor, and a first electrode of a light-emitting device corresponding to the driving transistor is electrically connected to a drain electrode of the driving transistor through at least one first via hole extending through the planarization layer and a corresponding auxiliary pattern.

17. The method according to claim 16, wherein forming the at least one first via hole extending through the planarization layer and the corresponding auxiliary pattern, includes:
forming a photoresist layer on a planarization film through a non-horizontal contact manner;
exposuring and developing the photoresist layer; and
etching the planarization film and the corresponding auxiliary pattern to form the at least one first via hole extending through the planarization layer and the corresponding auxiliary pattern.

18. The method according to claim 16, wherein before forming the at least one first via hole extending through the planarization layer and the corresponding auxiliary pattern, the method further comprises:
forming a second spacer film on a planarization film, a material of the second spacer film being an inorganic insulating material;
forming a photoresist layer on the second spacer film;
exposuring and developing the photoresist layer; and
etching the second spacer film to form a second spacer layer including a plurality of second via holes; and
forming the at least one first via hole extending through the planarization layer and the corresponding auxiliary pattern, includes:
etching the planarization film and the corresponding auxiliary pattern by taking the second spacer layer formed with the plurality of second via holes as a mask to form the at least one first via hole extending through the planarization layer and the corresponding auxiliary pattern.

19. The method according to claim 16, wherein before forming the at least one first via hole extending through the planarization layer and the corresponding auxiliary pattern, the method further comprises:
forming a second spacer film on a planarization film, a material of the second spacer film being a metal material;
forming a photoresist layer on the second spacer film;
exposuring and developing the photoresist layer; and
etching the second spacer film to form a second spacer layer including a plurality of second via holes; and
forming the at least one first via hole extending through the planarization layer and the corresponding auxiliary pattern, includes:
etching the planarization film and the corresponding auxiliary pattern by using the second spacer layer including the plurality of second via holes as a mask to form the at least one first via hole extending through the planarization layer and the auxiliary pattern; and
removing the second spacer layer.
